(19) United States
(12) Patent Application Publication
(10) Pub. No.: US 2009/0224411 A1
(43) Pub. Date: Sep. 10, 2009

(54) Multi-Chips Module Package Structure and the Method thereof

(76) Inventor: Shih-Chi CHEN, Hsinchu City (TW)

Correspondence Address: SINORICA, LLC, 2275 Research Blvd., Suite 500, ROCKVILLE, MD, 20850, US

(21) Appl. No.: 12/165,682

(22) Filed: Jul. 1, 2008

(30) Foreign Application Priority Data
Mar. 6, 2008 (TW) 097107790

(51) Int. Cl. H01L 23/48; H05K 1/03; H01L 21/56

(52) U.S. Cl. 257/778; 174/254; 174/250; 438/108; 257/E21.502; 257/E23.01

(57) ABSTRACT

A chip package structure includes a carrier substrate having a circuit in both front side and the reverse side; each chips includes a plurality of pads is arranged near the central region on the active surface; and a polymer material is used to cover the chips and the carrier substrate, the characteristic in that: the circuit of the front side is electrically connected to a plurality of first conductive points and a plurality of metal terminals by a plurality of metal trace, in which the plurality of metal trace is arranged on the reverse side by way of through hole on the carrier substrate, and the plurality of metal terminals of the reverse is electrically connected to the plurality of second conductive points by the plurality of second metal trace, in which the plurality of pads of the chips is electrically connected to the plurality of first conductive points and the part of metal terminals is to be exposed.

### BACKGROUND OF THE INVENTION

1. Field of the Invention

The present invention is a semiconductor package structure, and more particularly is a multi-chips module package structure and method thereof.

2. Description of the Prior Art

The integrated circuit usually semiconductor chips and is electrically connected to the lead-frame. The lead-frame is used to support the chips and is electrically connected to the chips and the circuit board. In this kind of circuit layout, the lead-frame and the chips are electrically connected to each other by some conductive lines, such as golden line or aluminum line and is covered by an encapsulated material. According to any different kinds of chips, the encapsulated material is made by ceramics or metal. When the chips is become smaller and smaller and the performance of the chips is become better and better, for any different electronic component, the multi-chip module system is a good way for the circuit layer. The multi-chip module system includes one or more chips and is able to increase the system operative speed by the longer connective line of the printed circuit board. In addition, the multi-chips module system is able to provide a better package efficiency.

Generally, the multi-chips module system is able to design in a single encapsulated material and includes one or more chips or includes some chips with same size and same function, such as single-line memory module (SIMM) or single-in-line package (SIP). For example, the multi-chips module system is made by 10 chips and the defective rate in each of the chips is 95%. In the first test of the system, the defective rate is more than 60%. When the multi-chips module system is made by 20 chips and the defective rate in each of the chips is also 95%. But, in the first test of the system, the defective rate is down to 36%. Therefore, the utilization of the multi-chips module system will be effected in the market.

### SUMMARY OF THE INVENTION

According to the problem described above, the main object of the present invention is to provide a chip package structure and put a plurality of known good chips on the carrier substrate with circuit layout. A burn-in step and a testing step are used to detect if there are any defected chips existed. If there are some defective chips, the defective chips are removed and the multi-chips module system is formed a plurality of individual packaged chips.

According the object described above, a carrier substrate with a plurality of circuits is provided herein and comprises a front side and a reverse side and each of the circuits is made in accordance with a plurality of first conductive points electrically connected to a plurality of metal terminals by a plurality of first metal traces, and the carrier substrate is characteristic by: the metal terminals are correspondingly disposed on a reverse surface of the carrier substrate by passing through the through hole of the carrier substrate and the metal terminals on the reverse ends are electrically connected to a plurality of second conductive points by a plurality of second metal traces.

A multi-chips module package structure comprises a carrier substrate, and the carrier substrate includes a front side and a reverse side and is made by a plurality of circuits; the plurality of the multi-chips are electrically connected to the circuits by flip chip and each of the multi-chips includes an active surface and a plurality of pads are disposed on a central region of the active surface and a polymer material is used to cover the multi-chips and a portion of the frond side of the carrier substrate, is characteristic by: each of the circuits on the front side of the carrier substrate is made by a plurality of first metal traces electrically connected to a plurality of first conductive points and a plurality metal terminals, and the metal terminals are correspondingly disposed on the reverse side of the carrier substrate by passing through a through hole of the carrier substrate; the metal terminals on the reverse side is electrically connected to a plurality of second conductive points by a plurality of second metal traces; wherein the pads on the active surface of each of the multi-chips are electrically connected to the first conductive points and exposed a portion of the metal terminals.

A multi-chips module package method is provided herein and comprises: providing a carrier substrate with a plurality of circuits and the carrier substrate includes a front side and a reverse side and each of the circuits on the front side of the carrier substrate is made by a plurality of first metal traces electrically connected to a plurality of first conductive points and a plurality of metal terminals; providing a plurality of chips, and each of chips includes an active surface and a plurality of pads are disposed on the active surface near a central region; disposing the chips on the carrier substrate and the pads on the active surface are electrically connected to the first conductive points; forming an encapsulated structure to cover the chips and the front side of the carrier substrate to expose the metal terminals by a polymer material; cutting the polymer material and the carrier substrate to form a multi-chips module package structure and the multi-chips module package structure is able to expose the metal terminals; wherein the carrier substrate further includes a portion of the metal terminals disposed on the reverse side of the carrier substrate by passing through a through hole of the carrier substrate and the metal terminals on the reverse side are electrically connected to the second conductive points by a plurality of second metal traces.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A-1C are top views illustrating that a first conductive point, a second conductive point a plurality of first metal traces and second metal traces disposed on the front side and the reverse side of the carrier substrate;

FIGS. 2A-2C are top views illustrating that the multi-chips disposed on the front side of the carrier substrate are electrically connected to the metal terminals on the carrier substrate;

FIG. 2D is A-A sectional view of FIG. 2A through FIG. 2C;

FIG. 2E is view illustrating that the conductive point and the metal terminals are exposed on the reverse side of the carrier substrate;

FIG. 2F is B-B sectional view of FIG. 2E;

FIG. 3 is a view illustrating that the failed chips are existed after packaging;

FIG. 4A is a view illustrating a package structure with single chip;

FIG. 4B is a view illustrating that a package structure with two chips; and

FIG. 5 is a flow chart illustrating that the package method for a multi-chips module package structure.

### DESCRIPTION OF THE PREFERRED EMBODIMENT

Some of the detail embodiments of the present invention will be described below. However, beside the detail description, the present invention can be generally used in other embodiments.

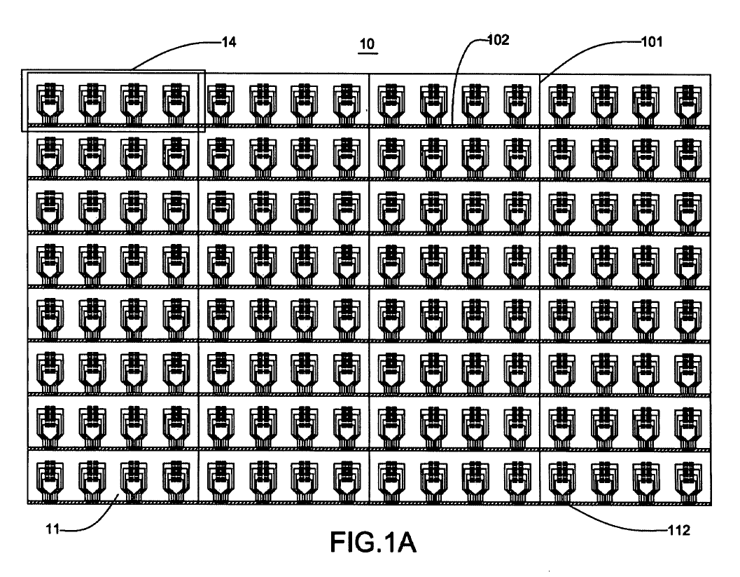

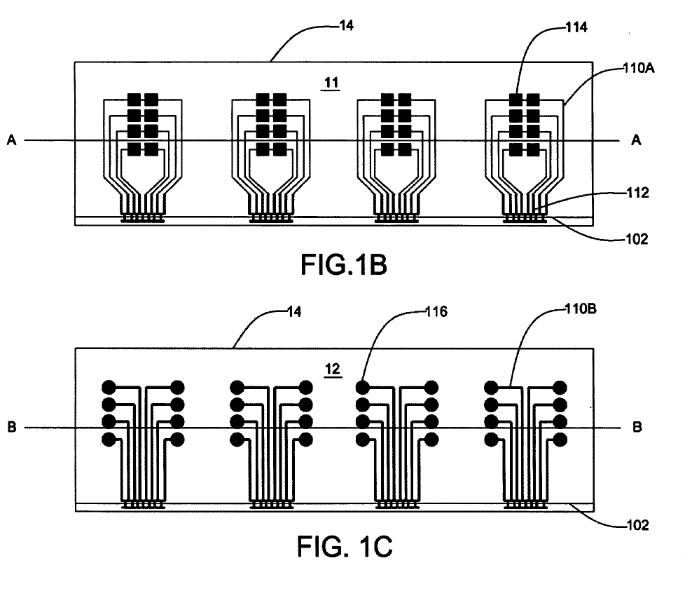

Now referring FIG. 1A to FIG. 1C, those are top views illustrating there are a first conductive point, a second conductive point and a plurality of first metal traces and second metal traces disposed on the front side and the reverse side of the carrier substrate. First of all, as shown in FIG. 1A, a carrier substrate 10 is provided herein and includes a front side 11 and a reverse side 12. The carrier substrate 10 is made by a plurality of circuits. Each line in the front side 11 of the circuits 14 is using a plurality of first metal trace 110A to electrically connect the first pad 114 and a plurality of the metal terminal 112. The first pad 114 is arranged by an array, especially as the pad 114 is connected to the dynamic random access memory (DRAM), such as 256 MB DRAM. The first pad 114 is disposed near the central region of the wire by a fan-in method. In addition, the first pad 114 is a golden bum and the metal terminal 112 is formed as a golden finger structure, as shown in FIG. 1B. It should be noted that, in the present embodiment, the position of the pads in each DRAMs are all the same, so the metal traces on the carrier substrate 10 can be used to be the wire layout to connect each of the DRAMs. For example, four DRAMs with same size, such as 256 MB, are willing to package together and formed a memory module with 1 GB. In addition, in the present embodiment, the DRAM size can be difference in a memory module in accordance with the requirement, it is not limited herein.

In addition, the metal terminal 112 is disposed on the reverse side 12 of the carrier substrate 10 by passing through the through-hole on the carrier substrate 10. As shown in FIG. 1C, there are a plurality of second conductive points 116 and a plurality of second metal traces 110B disposed on the reverse side 12 of the carrier substrate 10. The second conductive points 116 are electrically connected to the metal terminals 112 by the second metal traces 110B. The metal terminal 112 is electrically connected to the metal terminal disposed on the front side 11 of the carrier substrate 10. It should be noted that the second conductive points 116 are disposed around the wire region by fan-out method. Besides, the second conductive points 116 are pads or golden bumps. When the metal terminal 112 is formed the golden finger structure, an isolated material (such as plastics) (not shown) or a ceramic material is used to cover a portion of the metal terminal. Moreover, in the present invention, the carrier substrate 10 is a flexible substrate or a rigid substrate.

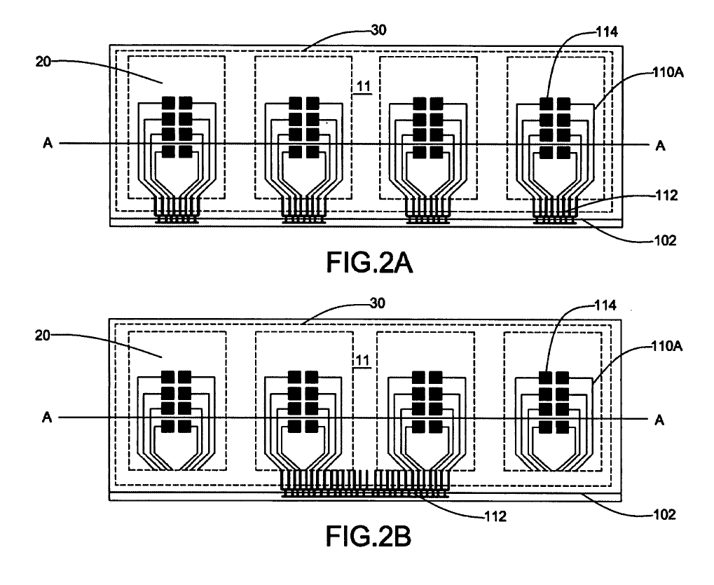

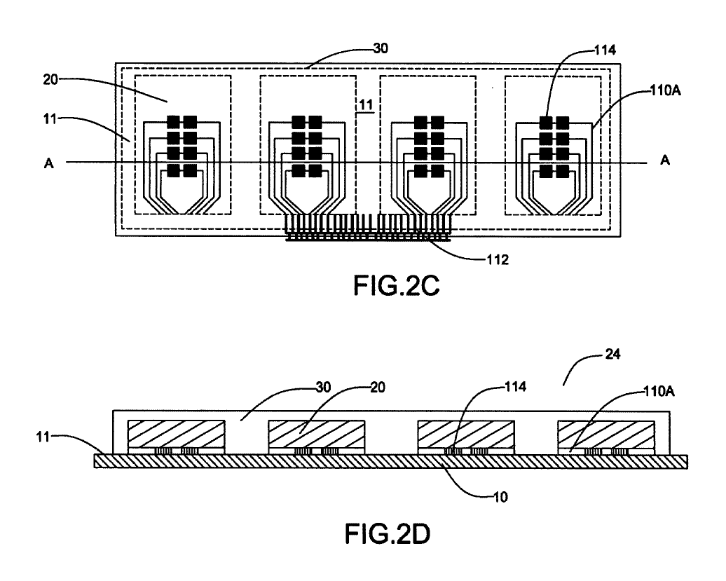

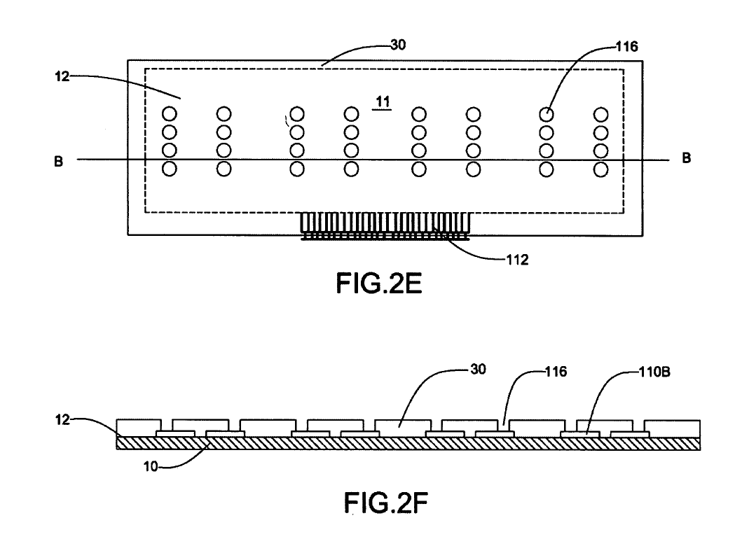

Now please referring to FIG. 2A and FIG. 2B, those are top views illustrating there are a plurality of chips disposed on the front side 11 of the carrier substrate 10 and electrically connected to a plurality of metal terminals on the carrier substrate 10. In the present embodiment, a wafer (not shown) is provided herein and a plurality of chips 20 disposed on the wafer. And a cutting process is used and let the reverse side of the chips 20 be upturned. And a delivery device (not shown) is used to absorb each of the chips 20 and put on the front side 11 of the carrier substrate 10. The pads on the active surface in each of the chips 20 are electrically connected to the first conductive points 114 disposed on the front side 11 of the carrier substrate 10. Each of the chips 20 is electrically connected to the metal terminals by the first conductive points and the first metal traces 110A, as shown in FIG. 2A.

Besides, when the delivery device will put the chip on the carrier substrate 10, the reference points, such as the first conductive points 114, can be used to calculate the corresponding position for each of the chips 20. In addition, the delivery device doesn't need to turn over the chips 20, so the chips 20 are able to correctly dispose on the carrier substrate 10.

Now referring FIG. 2B, it is another embodiment in the present invention. As shown in FIG. 2B, the metal terminals 112 on each of circuits of the carrier substrate 10 are centrally disposed on the moderate position of the circuit 14. Therefore, there is only one connective region installed on the corresponding plug. In addition, please referring FIG. 2C, it is another view according to FIG. 2B, the metal terminals 112 are also centrally disposed on the moderate position of the circuit, but the areas with the metal terminal 112 are exposed out of the around area of the carrier substrate 10. This way to design the corresponding plug is simple and saving the package materials.

After the chips are sequentially disposed on the carrier substrate 20, the encapsulating process is used. As shown in FIG. 2A, it is an enlarged view of the circuit 14 on the carrier substrate 10. As shown in FIG. 2A, the front side 11 of the carrier substrate 10 and the chips 20 are coated a polymer material layer 30 and the polymer material layer 30 is flattened by a molding device (not shown). The polymer material layer 30 is become a flattened surface and filled between the chips 20. The polymer material layer 30 is covered the chips 20 and exposing the metal terminal 112. Then, a baking procedure is optionally chosen to be processed on the polymer material layer 30 and the polymer material layer 30 is formed an encapsulated material, as shown in FIG. 2A to FIG. 2C. Obviously, the procedure is covering the front side 11 of the carrier substrate 10 but not covering the reverse side 12. So the second metal traces 110B, the second conductive points 116 and the metal terminal 112 on the reverse side 12 are exposed. It should be noted that FIG. 2D is also a view of the module package structure 24 in the present invention.

In addition, the encapsulated process in the present invention can use a molding process to encapsulate the circuit 14 of the carrier substrate 10 and expose the top end of the metal terminals by an up/down molding device (not shown). Subsequently, the polymer material is filled into the up/down molding device and the polymer material layer 30 is filled between the chips and covers the chips 20. Obviously, the process is also covering the front side 11 and the reverse side 12 of the carrier substrate 10 at the same time. The sectional view of the front side 11 is the same as shown in FIG. 2D. In the reverse side, the ends of the metal terminals 112 are exposed out of the reverse side or the second conductive points 116 and the ends of the metal terminals 112 are exposed out of the reverse side, as shown in FIG. 2E. The method to expose the second conductive points 116 is using the semiconductor package procedure, such as itching, to remove a portion of polymer material layer 30 and to expose the second conductive points on the reverse side 12 of the carrier substrate 10.

After the encapsulated procedure was done, the burin-in process or chip testing process is optionally preceded in the package procedure. The burin-in process is to put the semiconductor components in the burn-in board, which is able to work at high temperature and input some voltages or current in the semiconductor components in high temperature environment to speed up the lifetime of the semiconductor. And the chip testing process is used to do the probe test in each of the chips on the carrier substrate 10. A slim probe is installed on the test head and used to contact the connective trace on the chip to test the electrical property of the chip. The failed chip will be marked and removed after the sawing process.

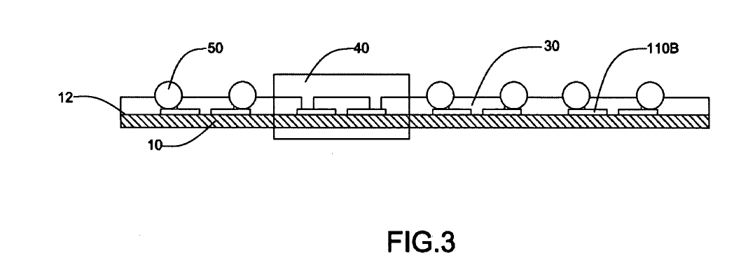

Because the encapsulated process in the present invention is used by a module method, a sawing knife is used to cut the wafer along a cutting line 101 or a cutting line 102 after the testing procedure described above. When the chip in each module package structure is normal, the encapsulated material is cut along the sawing path 101 or the sawing path 102 to form a plurality of module package structures 24. If one of the chips 20 in the module package structures 24 is failed, obviously the module package structure 24 is failed to have the function and size as design and the module package structure 24 needs to be eliminated. But three of the rest chips 20 in the module package structure 24 that is normal, the failed chip in the module package structure 24 can be removed. The electrical connective component 50 is formed in the second conductive point 116 of the normal chip in the module package structure 24. The failed chip 40 is not going to connect the electrical connective component 50, as shown in FIG. 3.

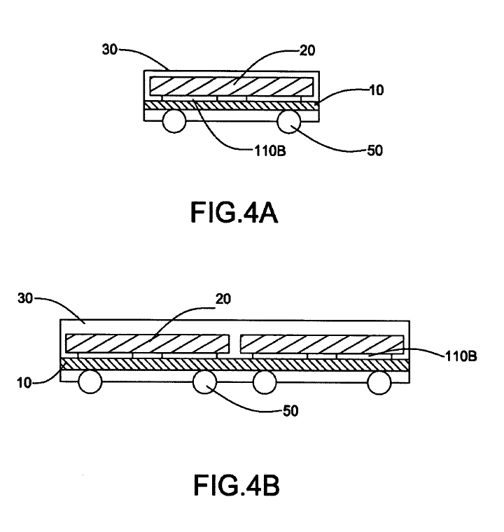

Subsequently, the module package structure 24 formed the electrical connective component 50 is doing the sawing process. The sawing method is to saw the edge of the polymer material layer 30 and the edge of the failed chip 40. The module package structure 24 with filed chip is sawed in a single chip 20 package structure, such as a 256 MB DRAM chip, as shown in FIG. 4A and a package structure with two chips 20, such as a 512 MB DRAM chips. In a different embodiment, the module package structure 24 with failed chip is sawed in a DRAM with three 256 MB chips. The module package structure 24 with failed chips is reusable and the manufacture cost can be reduced.

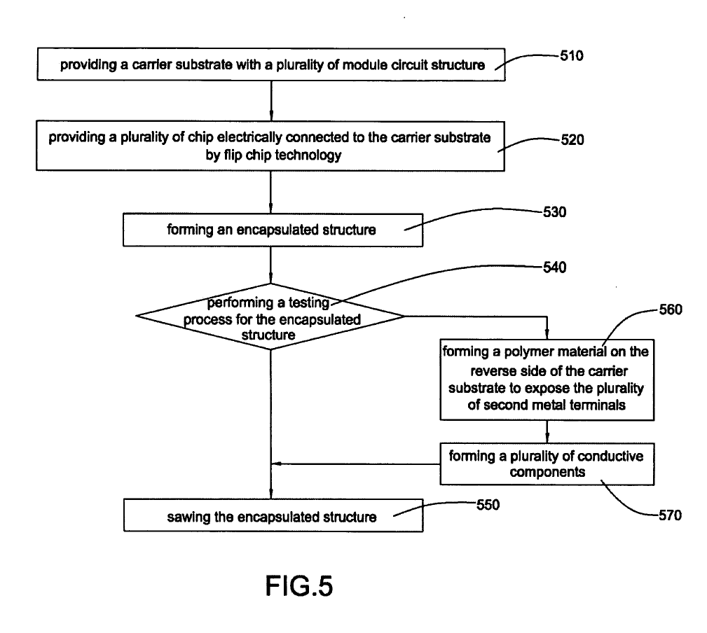

FIG. 5 is a flow char showing that the multi-chips module package method in the present invention. The steps of the multi-chips module package method are: The step 510 is to provide a carrier substrate with a plurality of circuits and the carrier substrate includes a front side and a reverse side and each of the circuits on the front side of the carrier substrate is made by a plurality of first metal traces electrically connected to a plurality of first conductive points and a plurality of metal terminals. The step 520 is to provide a plurality of chips, and each of chips includes an active surface and a plurality of pads are disposed on the active surface near a central region; The step 530 is to dispose the chips on the carrier substrate and the pads on the active surface are electrically connected to the first conductive points. The step 530 is to form an encapsulated structure to cover the chips and the front side of the carrier substrate to expose the metal terminals by a polymer material. The step 540 is to cut the polymer material and the carrier substrate to form a multi-chips module package structure. The step 550 is to cut the encapsulated material. The step of cutting the encapsulated material includes cutting polymer material layer and the carrier substrate to form a multi-chips module package structure and the multi-chips module package structure exposes a plurality of metal terminals. The carrier substrate further includes a plurality of metal terminals disposed on the reverse side of the carrier substrate by passing through the through hole on the carrier substrate. The metal terminals in the reverse side are electrically connected to the second conductive points by a plurality of second metal traces. If the failed chip is existed, the step 560 is used to form a polymer material layer on the reverse side and to expose the second metal traces. The, in step 570, it is to form a plurality of conductive components on the second conductive points. Then, the step 550 is used to cut the polymer material layer and the carrier substrate, and remove the metal terminals to form a plurality of packaged chip structures.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly and legally entitled.

What is claimed is:

1. A carrier substrate with a plurality of circuits comprising a front side and a reverse side and each of the circuits is made in accordance with a plurality of first conductive points electrically connected to a plurality of metal terminals by a plurality of first metal traces, and the carrier substrate is characteristic by:
the metal terminals are correspondingly disposed on a reverse surface of the carrier substrate by passing through the through hole of the carrier substrate and the metal terminals on the reverse ends are electrically connected to a plurality of second conductive points by a plurality of second metal traces.

2. The carrier substrate according to claim 1, wherein the carrier substrate is a flexible carrier substrate.

3. The carrier substrate according to claim 1, wherein the carrier substrate is a rigid carrier substrate.

4. A multi-chips module package structure comprises a carrier substrate, and the carrier substrate includes a front side and a reverse side and is made by a plurality of circuits; the plurality of the multi-chips are electrically connected to the circuits by flip chip and each of the multi-chips includes an active surface and a plurality of pads are disposed on a central region of the active surface and a polymer material is used to cover the multi-chips and a portion of the frond side of the carrier substrate, is characteristic by:
each of the circuits on the front side of the carrier substrate is made by a plurality of first metal traces electrically connected to a plurality of first conductive points and a plurality metal terminals, and the metal terminals are correspondingly disposed on the reverse side of the carrier substrate by passing through a through hole of the carrier substrate; the metal terminals on the reverse side is electrically connected to a plurality of second conductive points by a plurality of second metal traces; wherein the pads on the active surface of each of the multi-chips are electrically connected to the first conductive points and exposed a portion of the metal terminals.

5. The carrier substrate according to claim 4, wherein the carrier substrate is a flexible carrier substrate.

6. The carrier substrate according to claim 4, wherein the carrier substrate is a rigid carrier substrate.

7. The carrier substrate according to claim 4, wherein the multi-chips are memory chips with the same memory size.

8. The carrier substrate according to claim 4, wherein the multi-chips are memory chips with different memory size.

9. A multi-chips module package structure comprises a carrier substrate, wherein the carrier substrate includes a front side and a reverse side, and a plurality of circuits are electrically disposed on the front side and the reverse side; each of the multi-chips is electrically connected to the circuits on the front side by flip chip and each of the multi-chips includes an active surface and a plurality of pads are disposed on a central region of the active surface and a polymer material is used to cover the multi-chips and a portion of the frond side of the carrier substrate, is characteristic by:
the circuits on the front side of the carrier substrate is made by a plurality of first metal traces electrically connected to a plurality of first conductive points and a plurality metal terminals, and the metal terminals are correspondingly disposed on the reverse side of the carrier substrate by passing through a through hole of the carrier substrate; the metal terminals on the reverse side is electrically connected to a plurality of second conductive points by a plurality of second metal traces; wherein the pads on the active surface of the chip are electrically connected to the first conductive points and exposed a portion of the metal terminals.

10. The carrier substrate according to claim 9, wherein the second conductive points are exposed on the reverse side of the carrier substrate.

11. The carrier substrate according to claim 9, further includes a plurality of conductive components formed on the exposed second conductive points.

12. The carrier substrate according to claim 9, wherein the multi-chips are memory chips with the same memory size.

13. The carrier substrate according to claim 9, wherein the multi-chips are memory chips with different memory size.

14. A multi-chips module package structure comprises a carrier substrate, wherein the carrier substrate includes a front side and a reverse side, and is made by a plurality of circuits; each of the multi-chips is electrically connected to each of the circuits by flip chip and each of the multi-chips includes an active surface, and a plurality of pads are disposed on a central region of the active surface and a polymer material is used to cover the multi-chips and a portion of the frond side of the carrier substrate, is characteristic by:
the circuits on the front side of the carrier substrate is made by a plurality of first metal traces electrically connected to a plurality of first conductive points and a plurality metal terminals, and the metal terminals are correspondingly disposed on the reverse side of the carrier substrate by passing through a through hole of the carrier substrate; the metal terminals on the reverse side is electrically connected to a plurality of second conductive points by a plurality of second metal traces; wherein the pads on the active surface of the chip are electrically connected to the first conductive points and exposed a portion of the metal terminals.

15. The carrier substrate according to claim 14, wherein the second conductive points are exposed on the reverse side of the carrier substrate.

16. The carrier substrate according to claim 14, wherein the multi-chips are memory chips with the same memory size.

17. The carrier substrate according to claim 14, wherein the multi-chips are memory chips with different memory size.

18. A multi-chips module package method, comprising:
providing a carrier substrate with a plurality of circuits and the carrier substrate includes a front side and a reverse side and each of the circuits on the front side of the carrier substrate is made by a plurality of first metal traces electrically connected to a plurality of first conductive points and a plurality of metal terminals;
providing a plurality of chips, and each of chips includes an active surface and a plurality of pads are disposed on the active surface near a central region;
disposing the chips on the carrier substrate and the pads on the active surface are electrically connected to the first conductive points;
forming an encapsulated structure to cover the chips and the front side of the carrier substrate to expose the metal terminals by a polymer material;
cutting the polymer material and the carrier substrate to form a multi-chips module package structure and the multi-chips module package structure is able to expose the metal terminals;
wherein the carrier substrate further includes a portion of the metal terminals disposed on the reverse side of the carrier substrate by passing through a through hole of the carrier substrate and the metal terminals on the reverse side are electrically connected to the second conductive points by a plurality of second metal traces.

19. The package method according to claim 18, further comprising a step of executing a burn-in procedure before the step of cutting the polymer material.

20. The package method according to claim 18, after the step of cutting the polymer material, further comprising steps of:
forming another polymer material to cover the reverse side of the carrier substrate and exposing the second metal terminals if the failed chips are existed;
forming a plurality of conductive components on the second conductive points; and
cutting the polymer material and the carrier substrate and removing the metal terminals to form the plurality of multi-chips package structures.
